(19) United States
(12) Patent Application Publication
(10) Pub. No.: US 2026/0206325 A1
(43) Pub. Date: Jul. 16, 2026

(54) INTEGRATED CIRCUIT COMPRISING AT LEAST ONE ESD PROTECTING DEVICE

(71) Applicant: STMICROELECTRONICS INTERNATIONAL N.V., Geneva (CH)

(72) Inventors: Thalis DA COSTA GUEDES, Grenoble (FR); Johan BOURGEAT, Crêts en Belledonne (FR)

(21) Appl. No.: 19/444,579

(22) Filed: Jan. 9, 2026

(30) Foreign Application Priority Data
Jan. 14, 2025 (FR) 2500378

(51) Int. Cl. H10D 89/60; H10D 1/00; H10D 1/68; H10W 20/40; H10W 20/41; H10W 20/42; H10W 20/43

(52) U.S. Cl. CPC H10D 89/611; H10D 1/041; H10D 1/68; H10D 89/911; H10D 89/921; H10W 20/42; H10W 20/43; H10W 20/435; H10W 20/496

(57) ABSTRACT

The present description provides an integrated circuit comprising at least one device of protection against electrostatic discharges (ESD), the device comprising at least: a capacitive element comprising at least one metal-oxide-metal (MOM) capacitive element, comprising portions of metal interconnection levels of the integrated circuit; and an electronic ESD protection component, coupled in parallel with an MOM capacitive element and arranged, in the integrated circuit, vertically in line with the MOM capacitive element.

### CROSS REFERENCE TO RELATED APPLICATION(S)

This application claims the priority benefit of French Patent Application No. FR2500378, filed on Jan. 14, 2025, entitled “CIRCUIT INTEGRE COMPRENANT AU MOINS UN DISPOSITIF DE PROTECTION CONTRE DES DECHARGES ELECTROSTATIQUES”, the content of which is hereby incorporated by reference in its entirety to the maximum extent allowable by law.

### TECHNICAL FIELD

The present disclosure generally concerns the field of the protection of integrated circuits, or electronic chips, or electronic devices, against electrostatic discharges, or ESDs.

### BACKGROUND

Electrical capacitive elements, in particular formed by capacitors, are electronic components very common in integrated circuits. For example, RF (Radio Frequency) integrated circuits generally comprise many electrical capacitive elements used for the implementation of various electronic functions such as impedance matching, electrical decoupling, etc. These electrical capacitive elements are defined, in particular in terms of value and sizing, on design of the integrated circuit, without consideration of the ESD protection to be subsequently achieved to protect the circuit. ESD protection device(s), for example comprising electronic components of gated diode type, are generally added after the designing of the circuit, that is, after the lithography masks intended for the forming of the circuit have been finished.

ESD protection elements which are added to integrated circuits after their design however form parasitic electrical capacitive elements which, when they are not taken into account during the design of the integrated circuit, have a direct impact on the performance of integrated circuits, in particular in the case of RF integrated circuits. For example, the addition of parasitic electrical capacitive elements formed by the ESD protection devices can alter the impedance matching which has been pre-sized on design of an integrated circuit.

Further, when ESD protection devices have too high parasitic capacitance values, it cannot be envisaged to use them, on design of the circuit, as a capacitive element used for the implementation of electronic functions other than ESD protection, due to the fact that these functions generally require very low capacitance values, for example in the order of 10 fF.

### BRIEF SUMMARY

There exists a need to provide an ESD protection solution which does not have the disadvantages of already-existing ESD protection solutions.

An embodiment overcomes all or part of the disadvantages of known solutions and provides an integrated circuit comprising at least one device of protection against electrostatic discharges, ESD, the device comprising at least:
a capacitive element comprising at least one metal-oxide-metal, MOM, capacitive element comprising portions of metal interconnection levels of the integrated circuit;
an electronic ESD protection component, coupled in parallel with the MOM capacitive element and arranged, in the integrated circuit, vertically in line with the MOM capacitive element.

According to a specific embodiment, the MOM capacitive element is coupled to the ESD protection electronic component by vias extending between the MOM capacitive element and the ESD protection electronic component.

According to a specific embodiment, the ESD protection electronic component is arranged on top of and/or inside a semiconductor layer having the metal interconnection levels arranged opposite thereto.

According to a specific embodiment, the ESD protection electronic component corresponds to at least one of the following electronic components: diode, ggNMOS transistor, bipolar transistor, thyristor, TRIAC.

According to a specific embodiment, the device comprises a plurality of ESD protection electronic components corresponding to at least two diodes, each coupled in parallel with the MOM capacitive element and coupled to each other head-to-tail.

According to a specific embodiment, the device comprises a plurality of ESD protection electronic components corresponding to at least:
two first diodes coupled in series with each other and forming a first assembly of ESD protection electronic components coupled in parallel with the MOM capacitive element, and
two second diodes coupled in series with each other and forming a second assembly of ESD protection electronic components coupled in parallel with the MOM capacitive element,
and the cathode of one of the first diodes is coupled to the anode of one of the second diodes, and the cathode of another of the second diodes is coupled to the anode of another of the first diodes.

According to a specific embodiment, when the device comprises a plurality of ESD protection electronic components, the ESD protection electronic components are electrically coupled to each other at least by portions of other metal interconnection levels interposed between those having their portions forming the MOM capacitive element and the ESD protection electronic components.

According to a specific embodiment, the capacitive element further comprises at least one capacitive element formed by portions of the other metal interconnection levels interposed between those having their portions forming the MOM capacitive element and the ESD protection electronic components.

According to a specific embodiment, the value of the capacitive element is in the range from 5 fF to 1 pF, and for example equal to 10 fF.

According to a specific embodiment, the MOM capacitive element comprises portions of at least two metal interconnection levels.

According to a specific embodiment, the integrated circuit comprises other electronic components configured to implement radio frequency, RF, electronic functions, and the capacitive element is configured to cooperate with the other electronic components to implement at least part of the RF electronic functions.

There is also provided a method of forming at least one integrated circuit, comprising the forming of at least one electrostatic discharge protection device comprising at least:
the forming of an ESD protection electronic component;
the forming of a capacitive element comprising at least one capacitive element of metal-oxide-metal, MOM, type coupled in parallel with the ESD protection electronic component and comprising portions of metal interconnection levels of the integrated circuit and such that the ESD protection electronic component is arranged, in the integrated circuit, vertically in line with the MOM capacitive element.

According to a specific embodiment, the method further comprises the forming of vias arranged between the MOM capacitive element and the ESD protection electronic component and coupling the MOM capacitive element to the ESD protection electronic component.

According to a specific embodiment, the method further comprises steps of forming of other electronic components configured to implement RF electronic functions and the capacitive element is formed such that it is configured to cooperate with the other electronic components to implement at least part of the RF electronic functions.

According to a specific embodiment, the method further comprises, prior to the forming of the ESD protection electronic component and the forming of the capacitive element, a determination of a target electrical capacitance value of the capacitive element as a function of the RF electronic functions to be implemented, the capacitive element then being sized and formed in accordance with the determined target electrical capacitance value.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a circuit diagram of a first example of an ESD protection device used in an integrated circuit according to a specific embodiment;

FIG. 2 shows a simplified cross-section view of a portion of an integrated circuit comprising the first example of an ESD protection device according to a specific embodiment;

FIG. 3 shows a top view of a portion of an integrated circuit comprising the first example of an ESD protection device according to a specific embodiment;

FIG. 4 shows an equivalent impedance diagram of the first example of an ESD protection device according to a specific embodiment;

FIG. 5 shows equivalent admittance diagrams of the first example of an ESD protection device according to a specific embodiment;

FIG. 6 shows electrical capacitance values, as a function of an operating frequency, obtained with the first example of an ESD protection device according to a specific embodiment;

FIG. 7 shows electrical resistance values, as a function of an operating frequency, obtained with the first example of an ESD protection device according to a specific embodiment;

FIG. 8 shows quality factor values, as a function of an operating frequency, obtained with the first example of an ESD protection device according to a specific embodiment;

FIG. 9 schematically shows another example of an integrated circuit comprising an ESD protection device according to a specific embodiment;

FIG. 10 shows input gain values, as a function of an operating frequency, obtained in the integrated circuit shown in FIG. 9;

FIG. 11, FIG. 12, FIG. 13, and FIG. 14 show steps of a method of forming a portion of an integrated circuit comprising an ESD protection device according to a specific embodiment; and

FIG. 15 schematically shows a second example of an ESD protection device used in an integrated circuit according to a specific embodiment.

### DETAILED DESCRIPTION

Like features have been designated by like references in the various figures. In particular, the structural and/or functional features that are common among the various embodiments may have the same references and may dispose identical structural, dimensional and material properties. In the drawings, to make their reading easier, the various elements and the various layers of materials are not shown to the same scale.

For the sake of clarity, only those steps and elements that are useful for understanding the described embodiments have been shown and are described in detail. In particular, various elements (ESD protection electronic components, other electronic components of the integrated circuit, etc.) and various implemented steps (forming of the ESD protection electronic components, forming of the other electronic components of the integrated circuit, etc.) are not detailed. Those skilled in the art will be capable of designing in detail these elements based on the functional description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the terms “coupled” and “connected” are here used to refer to electrical links or connections.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, “lateral”, etc., or orientation qualifiers, such as “horizontal”, “vertical”, etc., reference is made unless otherwise specified to the orientation of the drawings. However, these terms do not presume the actual position and orientation of the device during its use.

Similarly, unless otherwise indicated, the indicated ranges of value include the limits of these ranges.

Unless specified otherwise, the expressions “about”, “approximately”, “substantially”, and “in the order of” signify plus or minus 10%, preferably of plus or minus 5%.

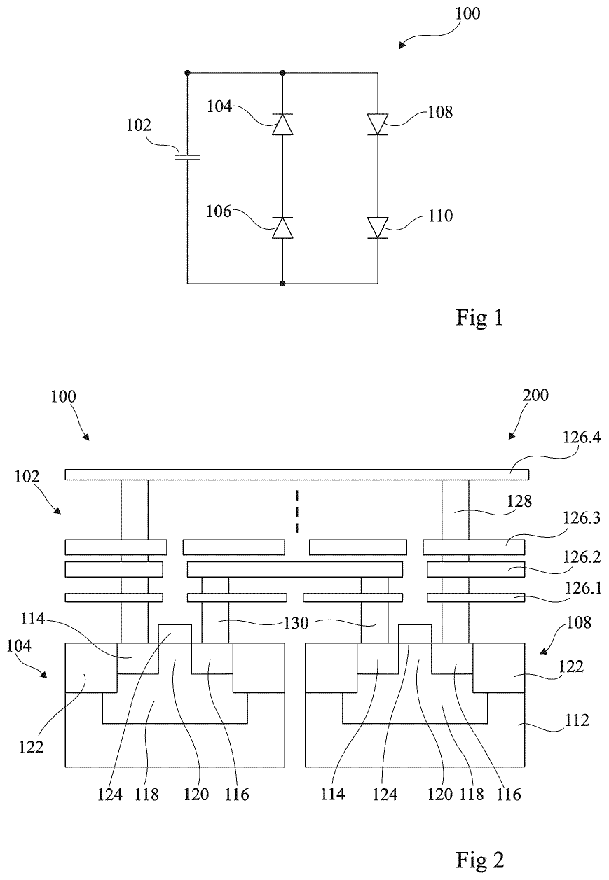

A first example of an electrostatic discharge protection device 100, or ESD protection device, used in an integrated circuit according to a specific embodiment is described hereafter in relation with FIG. 1.

Device 100 comprises at least one capacitive element comprising at least one capacitor 102 of metal-oxide-metal, MOM, type, comprising portions of metal interconnection levels of the integrated circuit having device 100 formed therein, this integrated circuit being intended to be protected from electrostatic discharges by device 100.

Device 100 also comprises at least one ESD protection electronic component, coupled in parallel with MOM capacitive element 102 and arranged, within the integrated circuit, vertically in line with MOM capacitive element 102. For example, the ESD protection electronic component of device 100 corresponds to at least one of the following electronic components: diode, gated diode, ggNMOS transistor (gate-grounded NMOS transistor), bipolar transistor, thyristor, TRIAC. As a variant, device 100 may comprise other types of electronic component enabling to discharge an electrostatic discharge current.

According to a specific embodiment, device 100 comprises a plurality of ESD protection electronic components. For example, in FIG. 1, device 100 comprises:
two first diodes 104, 106 coupled in series with each other and forming a first assembly of ESD protection electronic components coupled in parallel with MOM capacitive element 102, and
two second diodes 108, 110 coupled in series with each other and forming a second assembly of ESD protection electronic components coupled in parallel with MOM capacitive element 102.

According to a specific embodiment corresponding to that shown in FIG. 1, diodes 104, 106, 108, and 110 are of gated diode type.

In the example of FIG. 1, the cathode of one of the first diodes 104 is coupled to the anode of one of the second diodes 108, and the cathode of another one of the second diodes 110 is coupled to the anode of another one of the first diodes 106. Thus, in this example, the first assembly of ESD protection electronic components formed by the two first diodes 104, 106 is coupled in parallel to the second assembly of ESD protection electronic components formed by the two second diodes 108, 110.

In the described embodiment, the first assembly of ESD protection electronic components ensures the passage of an electrostatic discharge current flowing, in device 100, in a first direction, that is, having a first polarity, and the second assembly of ESD protection electronic components ensures the passage of an electrostatic discharge current flowing, in device 100, in a second direction opposite to the first direction, that is, having a second polarity opposite to the first polarity. As a variant, this function may be carried out by ESD protection electronic components or assemblies of ESD protection electronic components other than diodes.

According to an alternative embodiment, device 100 comprises a plurality of ESD protection electronic components corresponding to at least two diodes, each coupled in parallel with MOM capacitive element 102 and coupled to each other head-to-tail. A diagram of the device 100 according to this variant would correspond to that of FIG. 1, with only one of the two first diodes 104, 106 and only one of the two second diodes 108, 110.

According to another embodiment, device 100 may comprise a different number of first and second diodes, and more generally a number of ESD protection electronic components different from that of the example of FIG. 1. The number of ESD protection electronic components of device 100 may be selected according to the values of the voltages above which device 100 is intended to discharge electrostatic discharge currents. For example, in FIG. 1, device 100 comprises two first diodes 104, 106 coupled in series with each other and two second diodes 108, 110 coupled in series with each other so that the triggering of the ESD protection by device 100 occurs when the value of the electrostatic discharge voltage undergone by the circuit to be protected is greater than the sum of the threshold voltages of the two first diodes 104, 106 or of the two second diodes 108, 110, according to the polarity of the voltage to be discharged.

Other alternative embodiments of device 100, comprising a different number and/or other types of ESD protection electronic components, are possible.

A portion of an integrated circuit 200 comprising device 100 is shown in FIG. 2. Integrated circuit 200 comprises other electronic components, not shown in FIG. 2, and intended for the implementation of various electronic functions, for example RF electronic functions when integrated circuit 200 corresponds to an RF chip, and which are intended to be protected from electrostatic discharges by device 100.

According to a specific embodiment, the capacitive element, and in particular the MOM capacitive element 102, of device 100 is configured to cooperate with the other electronic components of circuit 200 to implement at least part of the electronic functions of circuit 200. For example, the capacitive element of device 100 may be used to perform an impedance matching at the input of circuit 200, or a capacitive decoupling within circuit 200.

In the example of FIG. 2, only the first diode 104 and the second diode 108 are shown. Each of diodes 104, 106, 108, and 110 is formed in a semiconductor layer 112, for example p-type doped. Semiconductor layer 112 forms, for example, an active layer of circuit 200 inside and/or on top of which the other electronic components of circuit 200 are formed. Semiconductor layer 112 may form or be part of a semiconductor substrate, and for example comprises silicon.

In the described example of embodiment, each of diodes 104, 106, 108, and 110 comprises at least one n+ doped region 114 having the cathode of the diode coupled thereto, as well as at least one p+ doped region 116 having the anode of the diode coupled thereto. Doped regions 114, 116 are, in this example, formed in an n-doped well 118, itself formed in semiconductor layer 112. In each of diodes 104, 106, 108, and 110, doped regions 114 and 116 are separated from each other by a portion 120 of doped well 118. In this example, in each of diodes 104, 106, 108, and 110, insulating regions 122, for example of STI (Shallow Trench Insulation) type, delimit the active area of each of them. In the described example of embodiment, each of diodes 104, 106, 108, 110 is of “gated diode” type, and comprises a gate 124 arranged vertically in line with the portion 120 of well 118 separating doped regions 114, 116. As a variant, the structures of diodes 104, 106, 108, 110 may be different from those shown in FIG. 2. As a variant, semiconductor layer 112 may be of type n, and well 118 may be p-doped.

The ESD protection electronic components of device 100 form part of the front end of line (FEOL) of circuit 200. Circuit 200 further comprises metal interconnection levels arranged above semiconductor layer 112 and forming part of the back end of line, or BEOL, of circuit 200. In FIG. 2, four metal interconnection levels 126.1 to 126.4 are shown. In the described example of embodiment, levels 126.1, 126.2, and 126.3 correspond to the metallization levels M1 to M3 of the BEOL of circuit 200, and level 126.4 corresponds to metallization level Mx, with x corresponding to an integer greater than or equal to 4, of the BEOL of circuit 200. In FIG. 2, the dielectric material(s) present between semiconductor layer 112 and the first metal interconnection level 126.1, as well as between the different metal interconnection levels 126.1 to 126.4, are not shown.

The MOM capacitive element 102 of device 100 is formed by portions of some of the metal interconnection levels of circuit 200. In the example of embodiment described in relation with FIG. 2, MOM capacitive element 102 is formed by portions of interconnection levels 126.3 and 126.4. As a variant, MOM capacitive element 102 may be formed by portions of other metal interconnection levels of circuit 200 and/or of a different number of metal interconnection levels of circuit 200.

According to an embodiment, the portions of each of the metal interconnection levels forming MOM capacitive element 102 are formed with interdigitated comb patterns. As a variant, other patterns or shapes of the portions of the metal interconnection levels forming MOM capacitive element 102 are possible.

In the described example of embodiment, MOM capacitive element 102 is coupled to the ESD protection electronic components, that is, to diodes 104, 106, 108, and 110 in the example of FIGS. 1 and 2, by first vias 128 extending between MOM capacitive element 102 and the ESD protection electronic components. In the example of FIG. 2, the first vias 128 extend between semiconductor layer 112 and metal interconnection level 126.4, through the other metal interconnection levels 126.1, 126.2, and 126.3. The first vias 128 may electrically couple together certain portions of these metal interconnection levels.

In the described specific example of embodiment, the ESD protection electronic components are electrically coupled together by portions of the metal interconnection levels which are interposed between those having their portions forming MOM capacitive element 102 and the ESD protection electronic components. In the example of FIG. 2, portions of metal interconnection levels 126.1 and 126.2 form connection elements electrically coupling diodes 104, 106, 108, and 110 to one another. These connection elements are electrically coupled to diodes 104, 106, 108, and 110 via second vias 130 extending between diodes 104, 106, 108, and 110 and metal interconnection levels 126.1 and 126.2.

In the described specific example of embodiment, the capacitive element of device 100 is formed by MOM capacitive element 102 but also by one or more other capacitive elements formed by portions of the metallic interconnection levels interposed between MOM capacitive element 102 and the ESD protection electronic components, that is, portions of interconnection levels 126.1 and 126.2 in the example of FIG. 2. Further, in the described example of embodiment, the capacitive element of device 100 also comprises parasitic electrical capacitive elements formed by the ESD protection electronic components themselves.

According to a specific example of embodiment, the surface area occupied by the metal interconnection levels used for the interconnection of the ESD protection electronic components of device 100, opposite the surface of semiconductor layer 112 above which the metal interconnection levels are arranged, is smaller than that of the metal interconnection levels forming MOM capacitive element 102. Device 100 may for example enable, for an occupied surface area equivalent to that of a conventional metal capacitive element, to form an ESD protection device provided with ESD protection electronic components and with a capacitive element of the same value as a conventional metal capacitive element, which would occupy a same surface area opposite semiconductor layer 112.

According to a specific embodiment, the value of the capacitance of device 100 is in the range from 5 fF to 1 pF, and for example equal to 10 fF. As a variant, depending on the value desired for the capacitance of device 100, it is possible for device 100 to comprise a plurality of MOM capacitive elements 102, each having a value for example in the range from 5 fF to 1 pF, and for example equal to 10 fF, enabling to obtain a device 100 having a capacitive value in line with the desired general electrical capacitance value. These MOM capacitive elements 102 may, for example, be arranged in an array. As a variant, it is possible for MOM capacitive element 102 to be sized such that its value is greater than 10 fF and equal to a desired electrical capacitance value.

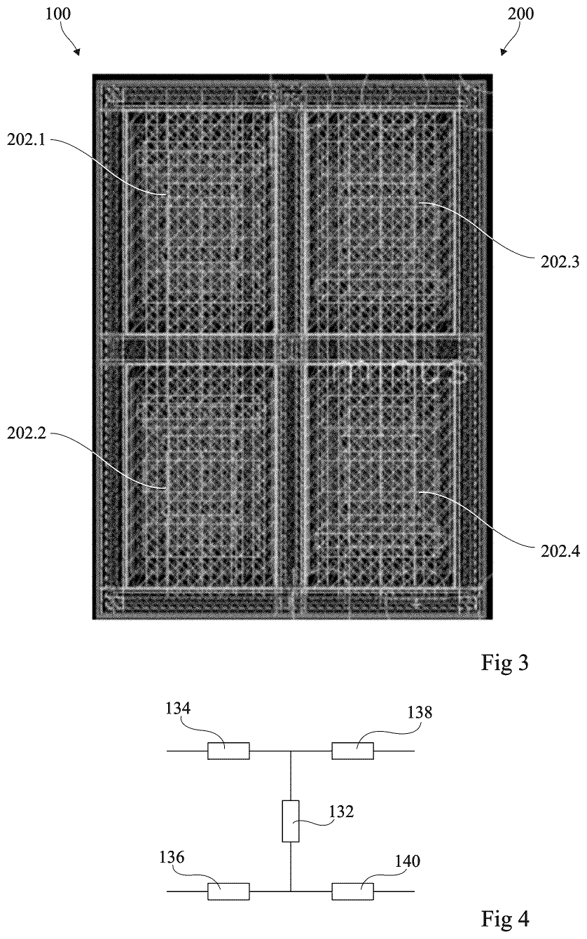

FIG. 3 schematically shows a top view of a portion of integrated circuit 200 comprising device 100. In this drawing, four rectangular regions 202.1, 202.2, 202.3, and 202.4 of circuit 200 are visible, each of them corresponding to a region in which one of diodes 104, 106, 108, and 110 is formed. The MOM capacitive element 102 of device 100 occupies, in this example, the entire surface area of the four regions 202.1 to 202.4. For example, the surface area occupied by this portion of integrated circuit 200 forms a rectangle having dimensions equal to 3.61 μm×5.01 μm.

FIG. 4 shows an electrical diagram of the real part of device 100, represented by the equivalent resistors formed by the elements of device 100. The resistive losses in device 100 are symbolized by resistor 132 (of value R_{cap}), and the internal parasitic resistances created by diodes 104, 106, 108, and 110 are respectively symbolized by inductances 134 (value Z₁), 136 (value Z₃), 138 (value Z₂), and 140 (value Z₄). The Z parameters corresponding to these impedances are:

Z₁₁=R_{cap}+Z₁+Z₃

Z₁₂=Z₂₁=R_{cap}

Z₂₂=R_{cap}+Z₂+Z₄

In this case, value R_{cap} is such that:

R_{cap}=½(Z₁₂+Z₂₁)=−2·Re((Y₁₂+Y₂₁)¹)

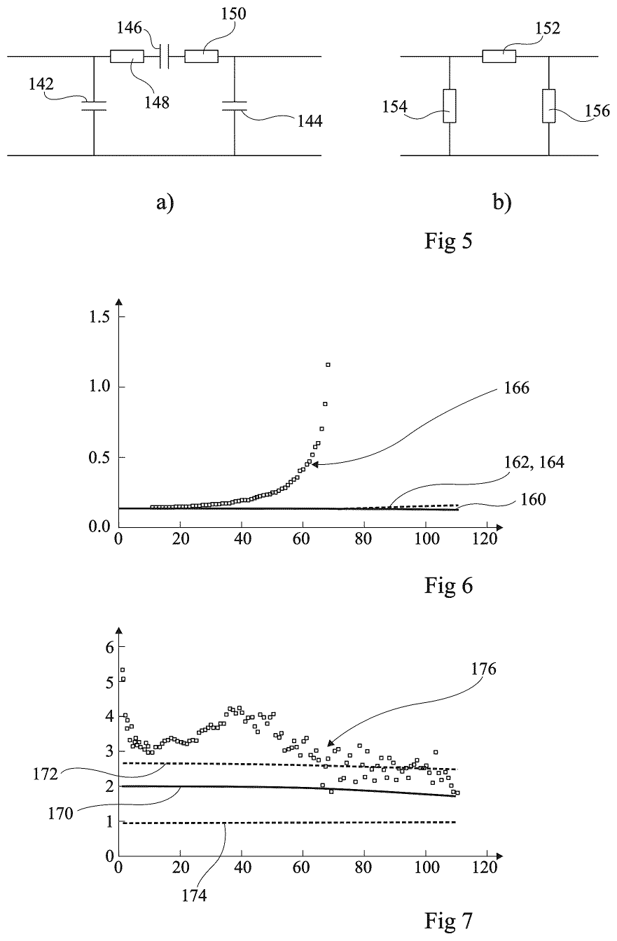

View a) of FIG. 5 shows an electrical diagram of the imaginary part of the device 100 of FIG. 1. Electrical capacitive element 146, of value C_{cap}, represents the capacitive element of device 100. Electrical capacitive elements 142 and 144 represent the parasitic capacitors which are formed due to the proximity of the conductive elements and of other elements of device 100. Impedances 148 and 150 represent the parasitic inductive part added by the internal connections of the integration. View b) of FIG. 5 shows equivalent admittances 152 (of value Y₁), 154 (of value Y₂), and 156 (of value Y₃) formed by the elements shown in view a). The Y parameters corresponding to these admittances are:

Y₁₁=Y₁+Y₂

Y₁₂=Y₂₁=−Y₁

Y₂₂=Y₁+Y₃

In this case, value C_{cap} is such that:

C_{cap}=1/(2ω·Im((Y₁₂+Y₂₁)⁻¹)

Curve 160, shown in FIG. 6, shows values of ideal electrical capacitance C_{cap}, in pF and as a function of an operating frequency (in GHz), obtained with the device 100 of FIG. 1, when MOM capacitive element 102 is equal to 150 fF. As a comparison, curves 162 and 164 represent ideal electrical capacitance values obtained with a MOM capacitive element having a value equal to 150 fF, using two different simulation models. The values designated by reference 166 correspond to measured values of MOM capacitive element 102 alone, without the other elements of device 100, as a function of the operating frequency.

Curve 170, shown in FIG. 7, shows the values of the resistive losses R_{cap}, in Ohms and as a function of the operating frequency (in GHz), of the device 100 of FIG. 1, when MOM capacitance 102 is equal to 150 fF. As a comparison, curves 172 and 174 show the resistive losses obtained with a MOM capacitance equal to 150 fF, using the two simulation models previously used to obtain curves 162 and 164. The values designated with reference numeral 176 correspond to those of the resistive losses measured on MOM capacitive element 102 alone, without the other elements of device 100.

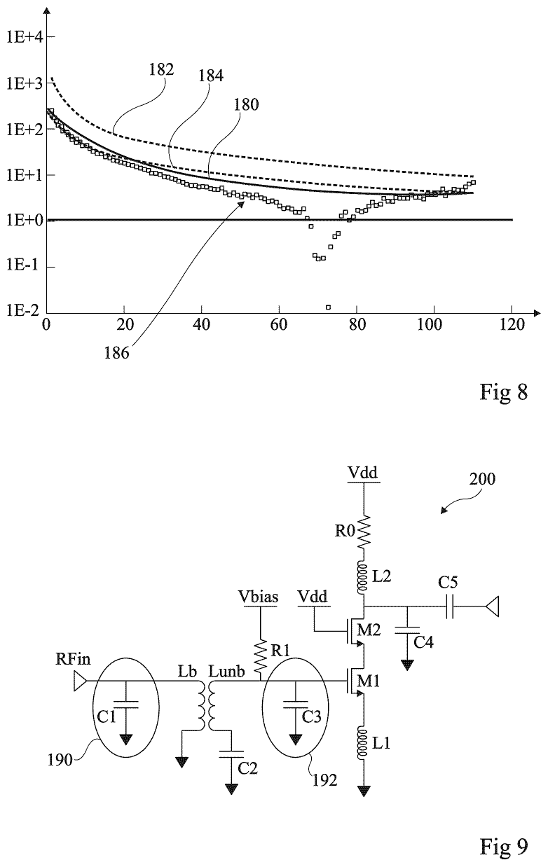

Curve 180, shown in FIG. 8, shows the values of the quality factor, as a function of an operating frequency (in GHz), of the device 100 of FIG. 1, when the MOM capacitance of capacitive element 102 is equal to 150 fF. As a comparison, curves 182 and 184 show the values of the quality factor obtained with a MOM capacitance having a value equal to 150 fF, using the two simulation models previously used to obtain curves 162, 164, 172, and 174. The values designated with reference numeral 186 correspond to those of the quality factor measured on the MOM capacitive element 102 alone, without the other elements of device 100.

The curves shown in FIGS. 6 to 8 show that the RF performance achieved by device 100 is not degraded for device 100 as compared with a conventional MOM capacitive element.

FIG. 9 shows another example of embodiment of an integrated circuit 200. In this example, circuit 200 corresponds to a low-noise amplifier (LNA) configured for a use in the RF domain. In this diagram, the capacitive elements designated with reference numerals 190 and 192 correspond to the MOM capacitive elements normally used for the impedance matching of circuit 200. The use of device 100 within such a circuit 200 amounts to replacing capacitive elements 190 and 192 with devices 100 such as previously described, which enables to achieve the same RF performance but with an integrated ESD protection.

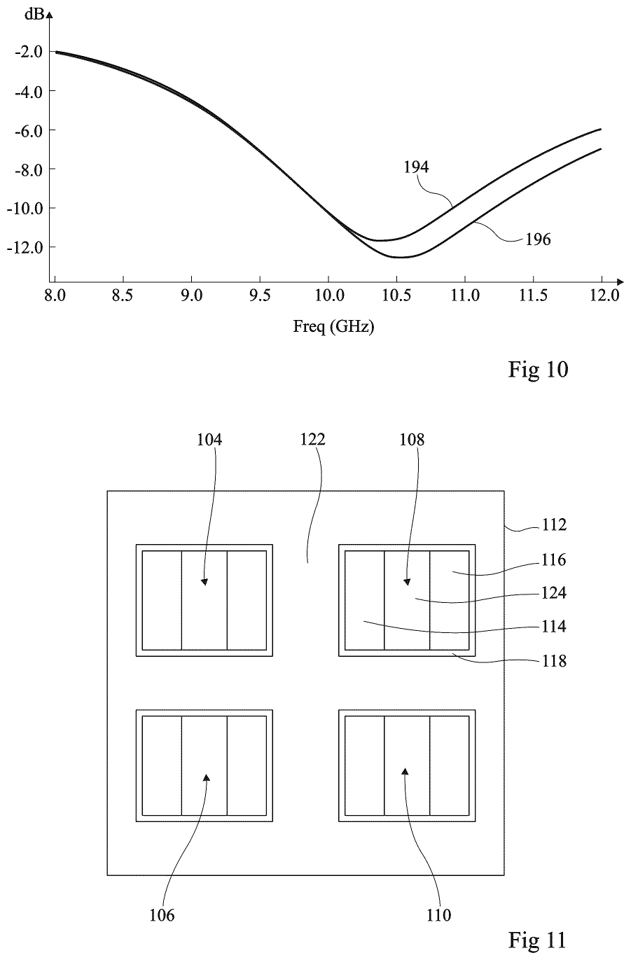

The curves 194 and 196 shown in FIG. 10 show values of the input impedance matching (Z₁₁), as a function of an operating frequency (in GHz), obtained with the amplifier of FIG. 9 when it comprises capacitors 190 and 192 (curve 194) and when these capacitors 190 and 192 are replaced by devices 100 (curve 196). These curves show a difference of less than −1 dB between the obtained input matching curves 194 and 196. These curves show that the use of device 100 does not alter, for an equivalent capacitance value, the input impedance of an integrated circuit in which one or more devices 100 are used as an ESD protection device.

The ESD protection provided on the gate of the transistor M1 of the amplifier of FIG. 9 in these two configurations is however different. As a general rule, a transistor can withstand a certain voltage V_{GS} depending on the technological node used and on the gate oxide thickness of the transistor, and for example equal to approximately 4.5 V. Accordingly, without an adapted protection, the amplifier cannot withstand an electrostatic discharge corresponding to the application of a voltage for example equal to 250 V CDM (Charged Device Model) on the pad RFin of the LNA, part of which will be transferred onto the gate of transistor M1. By using devices 100, this amplifier can withstand such an electrostatic discharge.

When the simulated circuit with which curve 194 is obtained, that is, comprising capacitors 190 and 192, is submitted to a 250-V CDM discharge on pad RFin, this circuit does not resist, due to a voltage V_{GS} greater than 6 V appearing on the gate of transistor M1 (the maximum voltage V_{GS} withstood in this case is 4.5 V), resulting in its destruction. When the simulated circuit with which curve 196 is obtained, that is, comprising devices 100 replacing capacitors 190 and 192, is submitted to the same 250-V CDM discharge, the voltage V_{GS} on the gate of transistor M1 is 1.51 V, and thus well below the maximum value withstood by transistor M1, which ensures that transistor M1 is not damaged. The same applies when the polarity of the CDM discharge voltage is negative.

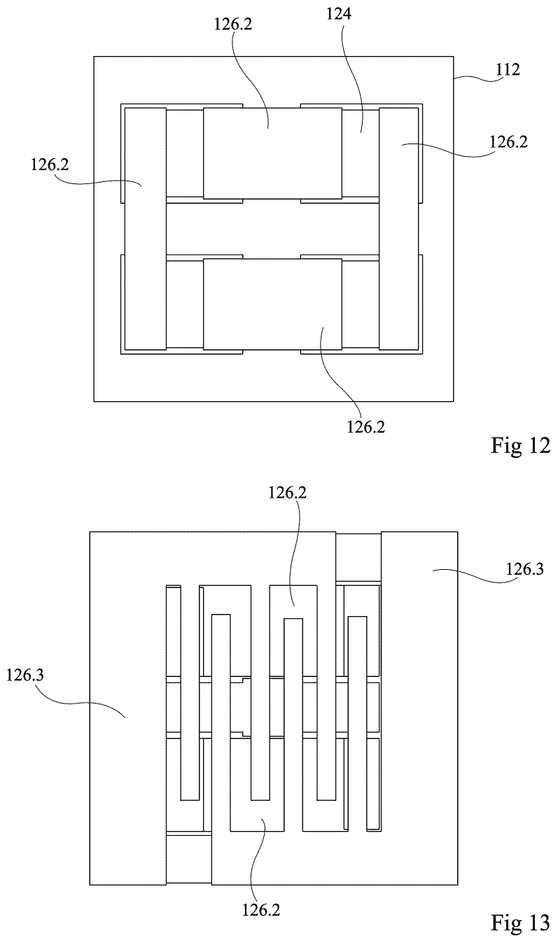

An example of a method of forming the previously-described circuit 200 and device 100, that is, comprising MOM capacitive element 102 and diodes 104, 106, 108, and 110 as previously described in relation with FIGS. 1 to 3, is described below in relation with FIGS. 11 to 14.

In the described example, prior to the forming of the different elements of device 100, a desired or target electrical capacitance value for the capacitive element of device 100 or of each of devices 100, and in particular for MOM capacitive element 102, is determined, for example by calculation, as a function of the electronic functions to be implemented by circuit 200. Based on this determined electrical capacitance value, the capacitive element, and in particular MOM capacitive element 102, is sized to be able to be formed in accordance with the determined value.

The ESD protection electronic component(s) is/are first formed. In the described example of embodiment, diodes 104, 106, 108, and 110 are manufactured in semiconductor layer 112 by, in particular, implementing a plurality of dopant implantation steps to form doped well 118 and doped regions 114 and 116. Steps of lithography, etching, and deposition are also implemented to form, in particular, insulating regions 122 and gates 124 (see FIG. 11).

Steps of forming other electronic components of circuit 200, for example configured to implement RF electronic functions when circuit 200 corresponds to an RF chip, are also implemented. These other components are not shown in FIGS. 11 to 14.

The BEOL part of circuit 200 is then formed. For this purpose, the first metal interconnection level 126.1, or level M1, is formed, in particular by the implementation of deposition and etching steps. In the described example of embodiment, the remaining, that is, unetched, portions of this first metal interconnection level 126.1, are arranged vertically in line with the doped regions 114 and 116 (these remaining portions of the first metal interconnection level 126.1 are not shown in FIGS. 11 to 14). The first metal interconnection level 126.1 is arranged on a dielectric material previously deposited on semiconductor layer 112 and not shown in the drawings.

The second metal interconnection level 126.2, or level M2, is then formed (see FIG. 12). The remaining portions of this second metal interconnection level 126.2 ensure, in particular, together with the portions of the first metal interconnection level 126.1, the electrical connections between the ESD protection electronic components, that is, between diodes 104, 106, 108, and 110 in the described example. The second metal interconnection level 126.2 is arranged on a dielectric material previously deposited and not shown in FIGS. 12 to 14. Second vias 130 are also formed (not shown in FIG. 12).

The MOM capacitive element 102 of device 100 is then formed vertically in line with the previously-formed ESD protection electronic components. For this purpose, the third metal interconnection level 126.3 is created. In the example of FIG. 13, the portions of this metal interconnection level are etched in the form of interdigitated combs to form an electrical capacitive element.

The fourth metal interconnection level 126.4 is then formed, as shown in FIG. 14. In this example, this metal interconnection level is etched such that the remaining portions of this level form interdigitated combs. First vias 126 are also formed between MOM capacitive element 102 and the ESD protection electronic components, through the different metal interconnection levels 126.1-126.4, thus coupling MOM capacitive element 102 to the ESD protection electronic components of device 100.

As a variant, it is possible for vias 126 and 128 to be formed in a plurality of steps and such that portions of the vias are formed during the forming of each of the metal interconnection levels.

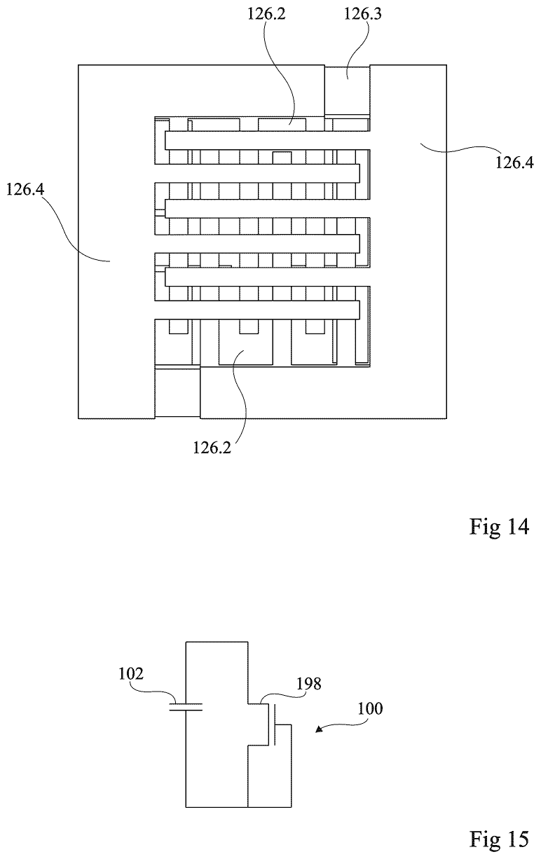

In the previously-described embodiments, device 100 comprises ESD protection electronic components corresponding to diodes. FIG. 15 schematically shows another example of embodiment of device 100 comprising a ggNMOS-type transistor 198 coupled in parallel with MOM capacitive element 102. Other types of ESD protection electronic components can be used instead of transistor 198.

In all embodiments and examples, the value of the capacitive element of device 100 can be very low, for example in the range from 5 fF to 1 pF or equal to 10 fF, in order to offer a maximum flexibility on design of an integrated circuit comprising device 100, also to allow a use of the capacitive element of device 100 as electronic components in the implementation of an electronic function other than ESD protection, and to enable, for example, a good parameterizing of the RF performance of the integrated circuit.

The provided device 100 and integrated circuit 200 enable to integrate ESD protection in a metal capacitive element of circuit 200, in particular by using one or more metal levels, not to form an electrical capacitive element, but to electrically couple the ESD protection electronic components to a MOM capacitive element formed above the ESD protection electronic components and in other metal interconnection levels. Such a configuration enables to use ESD capacitive elements, that is, the capacitive elements of devices 100, in various electronic functions on design of the integrated circuits. With device 100, at least one of the metal interconnection levels of integrated circuit 200 may not be used to form MOM capacitive element 102.

Device 100 may apply in particular to protect electronic chips or devices or RF-type integrated circuits. However, device 100 can be used as an ESD protection in any type of integrated circuit or electronic chip. Device 100 and integrated circuit 200 may concern, for example, at least one of the following fields: automotive industry; electric vehicles; industry; green energies; electrification of infrastructures such as charging or solar stations; Internet of Things; smart home; cloud computing; 5G networks; data center; computer servers; personal electronics; connected objects; electronic communications equipment; amplifiers; RF communication; LED lighting system.

Device 100 may form a solution of electrostatic discharge protection of HBM (Human Body Model) and CDM (Charged Device Model) type and having a capacitive value that can be modulated, with a protection level which increases as a function of the value of its electrical capacitance. The value of its electrical capacitance can be greater than or equal to 5 fF or 10 fF, and the electrical capacitive element can have the same dimensions as a standard metal capacitive element, without taking up additional space.

Device 100 can be used for the implementation of a protection of integrated circuit 200 against electrostatic discharges in accordance with the JEDEC JS001 standard, to provide ESD protection against discharges ranging up, for example, to 2 kV HBM, or in accordance with the JEDEC JS002 standard.

Device 100 may form a protection with an integrated electrical capacitive element, which allows for example a use within RF circuits and which can be directly adapted for an integration into the electronic functions of this circuit. Device 100 can thus avoid needing to perform an integration of parasitic capacitive element(s) linked to the ESD protection added to the integrated circuit to be protected.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. For example, the precise nature of the implemented deposition and etching steps can be selected in particular as a function of the material(s) to be deposited or to be etched, as well as of the thicknesses of material to be deposited or to be etched.

1. An integrated circuit comprising at least one device of protection against electrostatic discharges (ESD), wherein the at least one device comprises:
a capacitive element comprising at least one metal-oxide-metal (MOM) capacitive element comprising portions of metal interconnection levels of the integrated circuit; and
an ESD protection electronic component coupled in parallel with the MOM capacitive element and arranged, in the integrated circuit, vertically in line with the MOM capacitive element.

2. The integrated circuit of claim 1, wherein the MOM capacitive element is coupled to the ESD protection electronic component by vias extending between the MOM capacitive element and the ESD protection electronic component.

3. The integrated circuit of claim 1, wherein the ESD protection electronic component is arranged on top of or inside a semiconductor layer having the metal interconnection levels arranged opposite thereto.

4. Integrated circuit according to claim 1, wherein the ESD protection electronic component corresponds to at least one of: a diode, a gate-grounded NMOS (ggNMOS) transistor, a bipolar transistor, a thyristor, or a triode for alternating current (TRIAC).

5. Integrated circuit of claim 1, wherein the at least one device comprises a plurality of ESD protection electronic components corresponding to at least two diodes each coupled in parallel to the MOM capacitive element and coupled to each other head-to-tail.

6. The integrated circuit of claim 1, wherein the at least one device comprises a plurality of ESD protection electronic components comprising:
two first diodes coupled in series with each other and forming a first assembly of ESD protection electronic components coupled in parallel with the MOM capacitive element; and
two second diodes coupled in series with each other and forming a second assembly of ESD protection electronic components coupled in parallel with the MOM capacitive element,
and wherein a cathode of one of the two first diodes is coupled to an anode of one of the two second diodes, and a cathode of another of the two second diodes is coupled to an anode of another of the two first diodes.

7. The integrated circuit of claim 1, wherein, when the at least one device comprises a plurality of ESD protection electronic components, the plurality of ESD protection electronic components are electrically coupled to one another at least by portions of other metal interconnection levels interposed between those having their portions forming the MOM capacitive element and the plurality of ESD protection electronic components.

8. The integrated circuit of claim 7, wherein the capacitive element further comprises at least one capacitive element formed by portions of the other metal interconnection levels interposed between those having their portions forming the MOM capacitive element and the plurality of ESD protection electronic components.

9. The integrated circuit of claim 1, wherein a value of the capacitive element is in a range from 5 fF to 1 pF.

10. The integrated circuit of claim 1, wherein the MOM capacitive element comprises a plurality of portions of at least two metal interconnection levels.

11. The integrated circuit of claim 1, further comprising other electronic components configured to implement radio frequency (RF) electronic functions, and wherein the capacitive element is configured to cooperate with the other electronic components to implement at least part of the RF electronic functions.

12. The integrated circuit of claim 1, wherein the portions of each of the metal interconnection levels forming the MOM capacitive element comprise interdigitated combs patterns.

13. The integrated circuit of claim 1, wherein the at least one device further comprises a plurality of MOM capacitive elements arranged in a matrix.

14. A method of forming at least one integrated circuit, comprising a forming of at least one electrostatic discharge (ESD) protection device comprising at least:
a forming of an ESD protection electronic component; and
a forming of a capacitive element comprising at least one metal-oxide-metal (MOM) capacitive element, coupled in parallel with the ESD protection electronic component and comprising portions of metal interconnection levels of the at least one integrated circuit and such that the ESD protection electronic component is arranged, in the at least one integrated circuit, vertically in line with the MOM capacitive element.

15. The method of forming at least one integrated circuit of claim 14, further comprising a forming of vias arranged between the MOM capacitive element and the ESD protection electronic component and coupling the MOM capacitive element to the ESD protection electronic component.

16. The method of forming at least one integrated circuit of claim 14, further comprising steps of forming of other electronic components configured to implement RF electronic functions and wherein the capacitive element is formed such that it is configured to cooperate with the other electronic components to implement at least part of the RF electronic functions.

17. The method of forming at least one integrated circuit of claim 16, further comprising, prior to the forming of the ESD protection electronic component and the forming of the capacitive element, a determination of a target electrical capacitance value of the capacitive element as a function of the RF electronic functions to be implemented, the capacitive element then being sized and formed in accordance with the target electrical capacitance value determined.

18. The method of forming at least one integrated circuit of claim 14, wherein the portions of each of the metal interconnection levels forming the MOM capacitive element comprise interdigitated combs patterns.

19. The method of forming at least one integrated circuit of claim 14, wherein the at least one ESD protection device further comprises a plurality of MOM capacitive elements arranged in a matrix.
